(19) United States
(12) Patent Application Publication
(10) Pub. No.: US 2017/0025557 A1
(43) Pub. Date: Jan. 26, 2017

(54) BROADBAND REDUCED GRAPHITE OXIDE BASED PHOTOVOLTAIC DEVICES

(71) Applicant: GEORGIA TECH RESEARCH CORPORATION, Atlanta, GA (US)

(72) Inventors: Thomas Michael Orlando, Atlanta, GA (US); Anton Nickolaevich Sidorov, Atlanta, GA (US); Alex Elder, Atlanta, GA (US); Denis Aleksandrovich Sokolov, Mishawaka, IN (US)

(21) Appl. No.: 15/301,182

(22) PCT Filed: Apr. 2, 2015
(86) PCT No.: PCT/US15/24109

§ 371 Date: Sep. 30, 2016

Related U.S. Application Data
(60) Provisional application No. 61/973,881, filed on Apr. 2, 2014.

(51) Int. Cl. H01L 31/032; H01L 31/18; H01L 31/0203

(52) U.S. Cl. CPC H01L 31/0325; H01L 31/0203; H01L 31/18

(57) ABSTRACT

The embodiments of the disclosure relate generally to photovoltaic devices with broad band absorption in the solar light spectrum incident to Earth. The devices include integrated layers of graphite oxide and reduced graphite oxide, which exhibit intrinsic p/n junctions, which can be self-biasing and allow for production and separation of electron-hole pairs that can drive the current in the device. Descriptions of the devices and methods of making the structures are disclosed.

### CROSS REFERENCE TO RELATED APPLICATIONS

This application claims priority to U.S. Provisional Patent Application No. 61/973,881, filed Apr. 2, 2014 and entitled “Reduced graphene oxide broad band photovoltaic and integrated capacitive storage devices,” the contents of which are fully incorporated herein by reference.

### STATEMENT OF FEDERALLY SPONSORED RESEARCH

This invention was made with Government support under Grant No. DMR-0820382 awarded by the National Science Foundation. The Government has certain rights in this invention.

### TECHNICAL FIELD

Various embodiments of the present invention relate generally to reduced graphite oxide as a photovoltaic material that essentially eliminates the need for any hybrid inclusions (i.e. heterojunctions). The photovoltaic device can include integrated layers of reduced graphite oxide and graphite oxide to form an intrinsic p/n-junction capable of absorbing broadband light and forming electron-hole combinations that can drive the photovoltaic device.

### BACKGROUND

A major issue in the development of organic photovoltaic devices has been conversion losses due to recombination pairs at the donor-acceptor interface. Thus, improving the efficiency of organic photovoltaic materials based on heterojunction architectures has been a focus of many fundamental and applied research efforts. The incorporation of inorganic inclusions such as metallic and semiconducting nanoparticles to produce hybrid devices typically improves efficiencies, however, the gain/improvement is limited.

A major issue in the development of organic photovoltaic devices has been conversion losses due to recombination pairs at the donor-acceptor interface. Thus, improving the efficiency of organic photovoltaic materials based on heterojunction architectures has been a focus of many fundamental and applied research efforts. The incorporation of inorganic inclusions such as metallic and semiconducting nanoparticles to produce hybrid devices typically improves efficiencies, however, the gain/improvement is limited.

### BRIEF SUMMARY

Embodiments of the present invention are directed to various aspects of photovoltaic devices, including reduced graphite oxide photovoltaic devices containing one or more integrated layers of reduced graphite oxide and graphite oxide.

An embodiment of the disclosure can be a photovoltaic device, or a reduced graphite oxide photovoltaic device, having one or more integrated layers of reduced graphite oxide and graphite oxide, and current collectors located on different sections of the one or more integrated layers. The reduced graphite oxide can be intimately associated with the graphite oxide and can overlay the graphite oxide in the integrated layer. The reduced graphite oxide and graphite oxide can form an intrinsic p/n junction. In some embodiments, the reduced graphite oxide further includes an n-dopant, and/or the graphite oxide further includes a p-dopant.

In some embodiments, the graphite oxide can have an oxygen content of between about 10% and about 40%, between about 15% and about 40%, between about 15% and about 35%, or between about 15% and about 30%. In some embodiments, the reduced graphite oxide can have an oxygen content between about 1% and about 20%, between about 2% and about 15%, or between about 4% and about 14%.

In some embodiments, the photovoltaic device can include two or more integrated layers of reduced graphite oxide and graphite oxide. The oxygen content of the reduced graphite oxide layers in each of the two or more integrated layers can be the same or different in each layer. In some embodiments, the oxygen content of the reduced oxide can different in each layer and integrated layers establish of gradient of different oxygen content values.

In some embodiments, the integrate layer can include a reduced graphite layer and at least two different layers of graphite oxide, the graphite oxide layers having at least two different oxygen content values. When the oxygen content of the graphite oxide layers are different in each layer, a gradient of different oxygen content can be created.

An embodiment of the disclosure can include the integrated layers that absorb a broad band of light. The absorption can be for a broad band of visible light, or can be for a broad band of solar light incident to Earth's surface. The broad band of light can be between 300 nm and 3000 nm, between 400 nm to and 1000 nm, between 400 nm and 850 nm, or between 400 nm and 650 nm. A device that has at least two layers can also be designed to absorb different portions of a broad band of light, each portion being between 300 nm and 3000 nm.

An embodiment of the disclosure can also include a method of fabricating the photovoltaic device, or the reduced graphite oxide photovoltaic device. The method can include depositing at least one layer of graphite oxide over a first electrode, reducing a portion of the layer of graphite oxide to reduced graphite oxide to created an integrated layer of reduced graphite oxide and graphite oxide and depositing a second electrode over reduced graphite oxide. The method can further include adding additional integrated layers by depositing at least one layer of graphite oxide over the previous integrated layer; and reducing a portion of the graphite oxide to reduced graphite oxide to create the new integrated layer.

In some embodiments, the graphite oxide can be deposited as multiple layers. The graphite oxide layer can be deposited by spincoating or dropcasting. The graphite oxide layer can have a oxygen content as discussed above, and the reduced graphite oxide layer can also have an oxygen content as discussed above. For example, the oxygen content of the graphite oxide in at least one integrated layer can be between 15% and 40%, and the oxygen content of the reduced graphite oxide in at least one integrated layer can be between 1% and 20%.

The graphite oxide can be reduced to the reduced graphite oxide by a photolytic reduction. The photolytic reduction can be in an inert gas or under vacuum. The photolytic reduction can be with a high intensity light source such as laser processing, arc lamps, or flash lamps.

### BRIEF DESCRIPTION OF THE FIGURES

FIG. 1 is an illustration of a photovoltaic device containing an integrated layer of reduced graphite oxide and graphite oxide, in accordance with some embodiments of the disclosure.

FIG. 2 is another illustration of a photovoltaic device containing an integrated layer of reduced graphite oxide and graphite oxide, in accordance with some embodiments of the disclosure.

FIGS. 3A-E illustrate Raman spectra, SEM images, and conductive AFM images of an integrated layer of reduced graphite oxide and graphite oxide, in accordance with some embodiments of the disclosure.

FIGS. 4A-D illustrate X-ray photoelectron spectra of reduced graphite oxide and graphite oxide, in accordance with some embodiments of the disclosure.

FIGS. 5 A-E illustrate different measured characteristics of an integrated layer of reduced graphite oxide and graphite oxide, in accordance with some embodiments of the disclosure.

FIG. 6 illustrates a photovoltaic device containing an integrated layer of reduced graphite oxide and graphite oxide, in accordance with some embodiments of the disclosure.

### DETAILED DESCRIPTION

Although preferred embodiments of the disclosure are explained in detail, it is to be understood that other embodiments are contemplated. Accordingly, it is not intended that the disclosure is limited in its scope to the details of construction and arrangement of components set forth in the following description or illustrated in the drawings. The disclosure is capable of other embodiments and of being practiced or carried out in various ways. Also, in describing the preferred embodiments, specific terminology will be resorted to for the sake of clarity.

It must also be noted that, as used in the specification and the appended claims, the singular forms “a,” “an” and “the” include plural referents unless the context clearly dictates otherwise.

Also, in describing the preferred embodiments, terminology will be resorted to for the sake of clarity. It is intended that each term contemplates its broadest meaning as understood by those skilled in the art and includes all technical equivalents which operate in a similar manner to accomplish a similar purpose.

Ranges may be expressed herein as from “about” or “approximately” one particular value and/or to “about” or “approximately” another particular value. When such a range is expressed, another embodiment includes from the one particular value and/or to the other particular value.

By “comprising” or “containing” or “including” is meant that at least the named compound, element, particle, or method step is present in the composition or article or method, but does not exclude the presence of other compounds, materials, particles, method steps, even if the other such compounds, material, particles, method steps have the same function as what is named.

It is also to be understood that the mention of one or more method steps does not preclude the presence of additional method steps or intervening method steps between those steps expressly identified. Similarly, it is also to be understood that the mention of one or more components in a device or system does not preclude the presence of additional components or intervening components between those components expressly identified.

This disclosure presents a novel method of photolytic, or light-induced, reduction of graphite oxide that creates a graphene based material with a unique and useful morphology that can eliminate the need for any hybrid inclusions (i.e. heterojunctions). As an example, an excimer laser reduction can produce an uneven oxygen doping distribution and resultant intrinsic gradients.

Described herein are applications the use of and preparation of reduced graphite oxide on a photovoltaic material that essentially eliminates the need for any hybrid inclusions (i.e. heterojunctions). A reproducible method for the fabrication of large-scale freestanding reduced graphite oxide films and their use for the self-powered broadband light sensing and photovoltaic applications is described. By development of the reduction method, including for example laser reduction methods, a unique topography and buried interface is produced which completely eliminates the need for any additional hybrid material incorporation. These buried interface structures can break the mirror symmetry of the internal electric-fields and lead to efficient photoconversion and separation of charge carriers over a very broadband frequency range. Since the collection and transport of charge carriers by the reduced graphene oxide can be very efficient, this material and process provides a unique and inherently scalable method for producing efficient broadband organic semiconductor devices that can operate with zero source-drain bias.

Since graphene, a monatomic layer of hexagonally arranged carbon atoms, was first deposited on a dielectric substrate in 2004, it has attracted great interest from the physics, chemistry and materials science communities. Graphene can formally be considered as single sheets of graphite, and much work has gone into developing applications with the material, such as being used as conductive electrodes in electronic systems. The material's sheet strength, transparency, and high electrical and thermal conductivities make it very attractive in several industries. However, one hurdle to overcome has been the reliable, affordable and applicable routes to producing the graphene. Routes that have been used to attempt to produce graphene include chemical, thermal, and phototreductions, but definitive production of free standing graphene, as demonstrated by the characteristic G′ peak in Raman spectra, has been limited.

In the course of related efforts to develop graphene via photolytic reduction, it was discovered that a combination of reduced graphite oxide and graphite oxide demonstrated surprising electronic band gap characteristics that could be applied to photovoltaic devices and structures. The combination of a graphene-type layer in integrated contact with a graphite oxide layer produces an intrinsic p/n junction. The application of light to the integrated layer can produce an electron-hole pair that can separate and be used to drive a photovoltaic system. Moreover, the range and types of light are not limited to narrow ranges of the spectrum, but can be applied across the broad band of near UV, visible, and near-IR wavelengths.

As used herein, graphite oxide, which can be abbreviated “GO,” is a material known to one of ordinary skill in this area, and represents an oxidized form of graphite. Without wishing to be bound by theory, the oxidation routes of graphite to graphite oxide can produce hydroxyls, epoxides, and carbonyl structures in the graphite, and serve at least in part to delaminate the starting graphite. One traditional route for preparing graphite oxide is via the Hummers method, or a modified Hummers method, but other sources of graphite oxide can be utilized in this disclosure.

As used herein, reduced graphite oxide is a material that can be produced by reduction of graphite oxide. Reduced graphite oxide can also commonly be referred as graphene, or graphene oxide, or reduced graphene oxide, and can be abbreviated “rGO.” The goal in much of graphene technology has been to delaminate graphite via an oxidation, then subsequently reduce it to produce a graphene-type material, which could be applied to different technologies. Numerous chemical and thermal techniques have been attempted.

Unlike other routes of graphene production, such as chemical or thermal conversions, the photolytic reduction of graphite oxide can produce a layer of reduced graphite oxide that is on top of a layer of graphite oxide. Surprisingly, it has been discovered that this integrated layer of reduced graphite oxide and graphite oxide demonstrates properties applicable to photovoltaic systems. As part of the disclosure, the conversion of graphite oxide to reduced graphite oxide via photolytic reduction produces an integrated layer of graphite oxide and reduced graphite oxide with an intrinsic p/n junction, without requiring additional heteromaterials, such as inorganic compounds or complexes used as one of the materials to create a band-gap in the photovoltaic system.

An embodiment of the disclosure can be a reduced graphite oxide photovoltaic device comprising one or more integrated layers of reduced graphite oxide and graphite oxide, and current collectors located on different sections of the one or more integrated layers. Another embodiment can be a photovoltaic device comprising one or more integrated layers of reduced graphite oxide and graphite oxide. By integrated is meant that the graphite oxide and the reduced graphite oxide are closely associated, which can be achieved by the photolytic process because the reduce graphite oxide layer is on one side of the graphite oxide layer. The reduced graphite oxide layer can also overlay the graphite oxide layer, and can be intimately associated with the layer, meaning that the boundary between the reduced graphite oxide and the graphite oxide is indistinguishable. The reduced graphite oxide layer generally will not encapsulate the graphite oxide layer, primarily because the photolytic reduction occurs only on the side exposed to the light source.

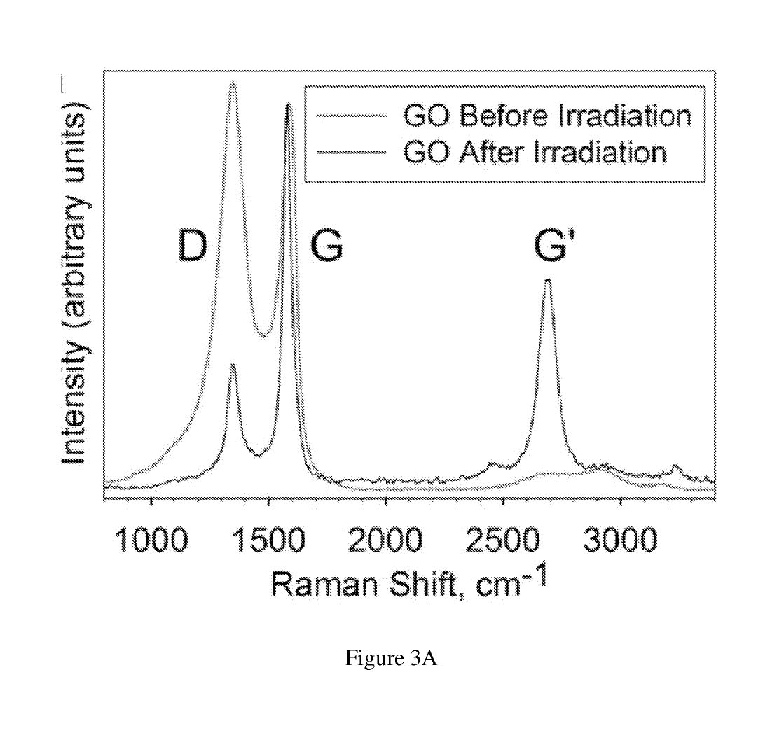

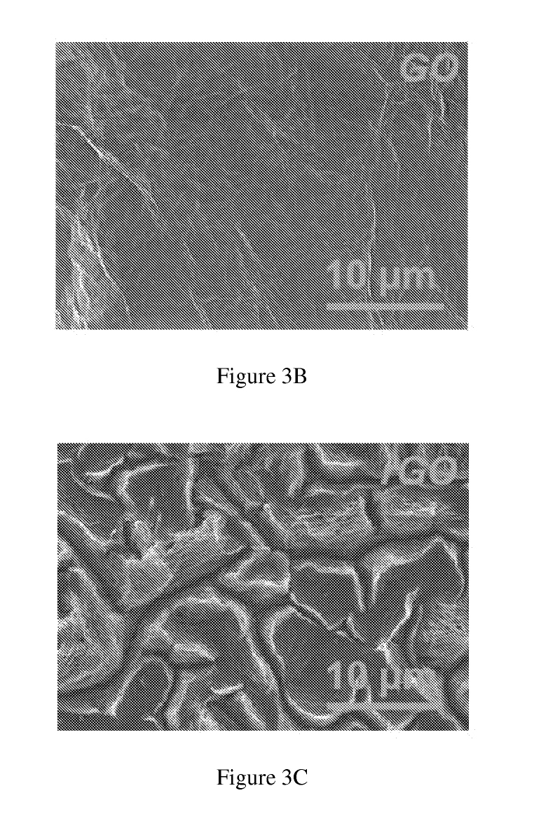

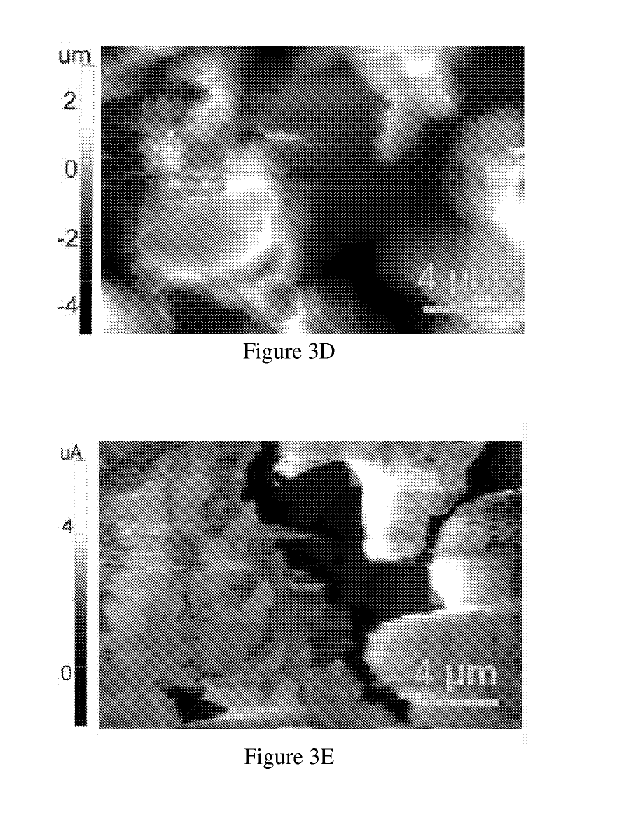

The reduced graphite oxide and graphite oxide in contact with on another form an intrinsic p/n junction, such that the material can absorb a photon of light to form an electron-hole pair which can be separated and utilized to drive the photovoltaic device. Without wishing to be bound by theory, the reduced graphite oxide can form as asymmetric segments and valleys in the graphite oxide layer that it is integrated with (see, e.g. FIG. 3C). These asymmetric segments and valleys form uneven internal E-fields that may be partially responsible for the separation of the photo-generated carriers, allowing separation of the electron to the graphene and the hole to the graphite oxide. As discussed in more detail below, the current passing through the sample at low fields is controlled by high resistance segments. As the photo-generated voltage rises, the injection of the space charge begins to determine the current in the high-resistance segments. At the appropriate level of injection, the resistance of these segments becomes commensurate with that of the low-resistance segments and the asymmetrical nature of the internal E-fields throughout the device surface generates photocurrent across the whole sample.

While the integrated layer forms an intrinsic p/n junction, the use of other dopants is not precluded. N-dopants can be utilized to enhance the graphene layer, and P-dopants can be used to enhance the graphite oxide layer. For example, the reduced graphite oxide layer can be enhanced with n-doping by incorporating nitrogen atoms from a nitrogen atmosphere into the reduced graphite oxide, via a localized plasma of nitrogen above the graphene surface. As another example, a p-dopant could be included in the graphite oxide layer during deposition of graphite layers as discussed below. As yet another example, an n-dopant could be included into an upper layer of graphite oxide deposited via a layering process, and the upper layer reduced to form an n-doped reduced graphite oxide. [CONFIRM]

Another embodiment of the disclosure can be the oxygen content of the graphite oxide. In an embodiment, the graphite oxide can have an oxygen content of greater than 10%, and can have a oxygen content of less than about 45%. The graphite oxide can have an oxygen content between about 10% and about 40%, between about 15% and about 40%, and between about 15% and about 35%. The graphite oxide content can have an oxygen content between about 15% and about 25%, between about 20% and about 30%, or between 25% and about 35%. The percentage here is atom%, based on XPS measurements. The C/O ratio of the graphite oxide can be between above 1 and about 10, between about 1.5 and about 8, or between about 1.5 and about 6.

The graphite oxide can be composed of different sections of graphite, based on layering or depositing different graphite oxides on top of each other. In an embodiment, the graphite oxide in the integrated layer can be composed of one section, two sections, or numerous sections of graphite oxide. With different graphite oxide sections in the graphite oxide of the integrated layer, the graphite oxide can have an oxygen content that varies across the material. For example, a lower section of a graphite oxide could have an oxygen content of between about 30% and about 35%, an intermediate section of the graphite oxide could have an oxygen content about between about 20% to 25%, and an upper section of the graphite oxide could have an oxygen content of between about 10% and about 20%. The range in oxygen contents in the graphite oxide could be graduated from high to low, or from low to high. The range of oxygen contents in the graphite oxide could also be randomized, or could be alternated. In general, the oxygen content of the graphite oxide can be controlled by the oxidation of the source used to layer the graphite oxide, e.g. different oxidation levels of different graphite oxides based on the method of preparing the graphite oxide.

Another embodiment of the disclosure can be the oxygen content of the reduced graphite oxide. In an embodiment, the reduced graphite oxide can have an oxygen content greater than about 1% and can have a oxygen content of less than about 20%. The oxygen content of the reduced graphite oxide can be between about 2% and about 20%, between about 2% and about 15%, and between about 4% and about 14%. The oxygen content of the reduced graphite oxide can be between about 2% to about 8%, between about 4% and about 10%, or about 8% to about 15%. The percentage here is atom%, based on XPS measurements. The C/O ratio of the reduced graphite oxide can be above about 5, and below about 100. The C/O ratio of the reduced graphite oxide can be between about 5 and about 50, between about 5 and about 30 or between about 5 and about 25. The C/O ratio of the reduced graphite oxide can be between about 10 and about 30, or between about 15 and about 30.

The thickness of each integrated layer can be controlled primarily by the thickness of the graphite oxide initially deposited. The integrated layer can have a thickness of at least about 10 nm, at least about 30 nm, at least about 50 nm, at least about 100 nm, at least about 300 nm, or at least about 500 nm. The integrated layer can have a thickness from about 100 nm to about 50 μm, or from about 500 nm about 40 μm, or from about 1 μm to about 30 μm. Integrated layer can have a thickness of up to 1000 μm, up to 750 μm, up to 500 μm, or up to 250 μm.

The photovoltaic device can contain at least one integrated layer of reduced graphite oxide and graphite oxide. The device can contain more than one integrated layer, including two, three, four, five or more integrated layers, each layer containing the reduced oxide and graphite oxide. In an embodiment, the oxygen content of the reduced graphite oxide in each layer can be the same amongst the integrated layers, or it can be different. In an embodiment, the oxygen content of the graphite oxide in each integrated layer can also be the same among the integrated layers, or can be different.

An embodiment of the disclosure is the ability of the integrated layers to absorb a broad band spectrum of light when incorporated into a photovoltaic device. The device having the integrated layers of reduced graphite oxide and graphite oxide can absorb a broad spectrum of light, including from about 250 nm to about 3000 nm, from the near UV to the near IR. In effect, the materials of the device are able to absorb the full range of the solar spectrum incident on Earth's surface. Because of this broadband capability, the efficiency of the disclosed devices can be higher than other current devices that only capture a small portion of the solar spectrum. In an embodiment, the device can absorb wavelengths between 300 and 3000 nm, between 400 and 1000 nm, and between 400 and 800 nm. By “absorption” is meant that at least a non-trivial portion of the light of a particular wavelength is absorbed by the device. Without wishing to be bound by theory, the absorption can occur in the graphite oxide, and the graphite oxide can be tailored via oxygen content, including gradients of oxygen content, to capture a broad range of light. The oxygen content of graphite oxide can be directly correlated to the wavelength of light it absorbs, based on the bandgap of graphite oxide as determined by its degree of oxidation. Thus, each layer of graphite oxide can be designed to absorb a certain section of the visible spectrum, and multiple layers can be designed to cover the broad range. Moreover, sections of graphite oxide can be tuned to a particular penetration depth for the wavelength range that it is intended to absorb.

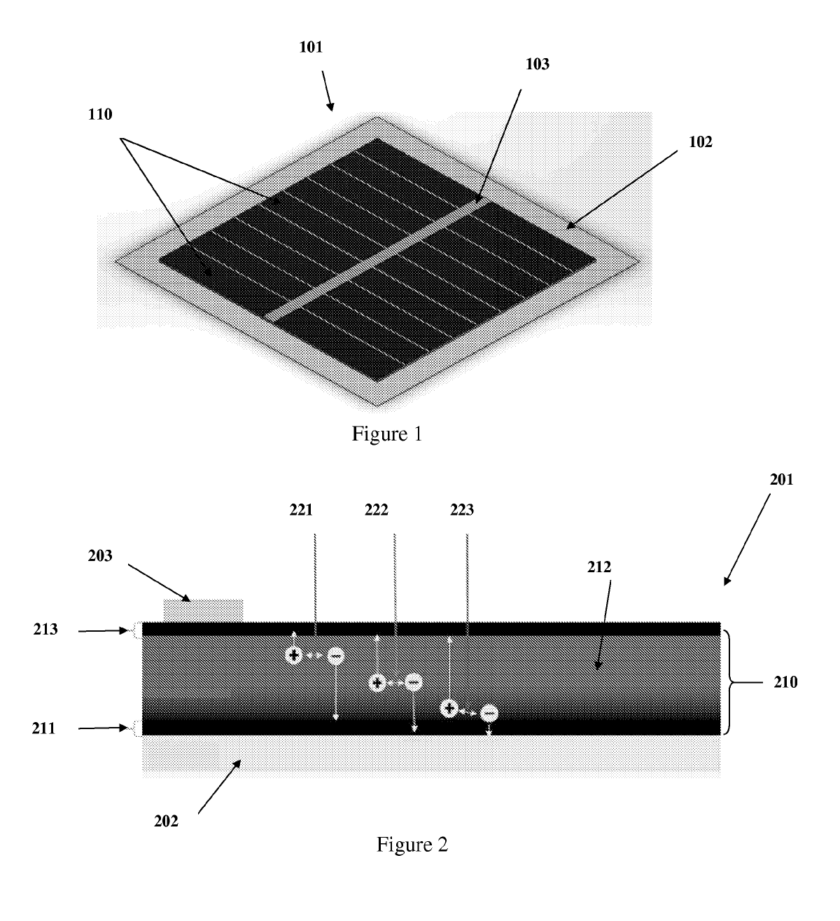

FIGS. 1 and 2 then demonstrate an exemplary embodiment of the device. An exemplary photovoltaic device with integrated layers is shown in FIG. 1. Photovoltaic device 101 includes a conductive backing 102 and an electrode contact 103, positioned on top of the integrated layers 110. FIG. 2 shows a side-on perspective of a photovoltaic device 201 having an integrated layer 210, a conductive backing 202 and electrode contact 203. The integrated layer 210 can include a reduced graphite oxide later 211, and a graphite oxide layer 212. An additional conductive layer 213 can be cast on the top, in contact with the electrode contact 203, and can also be a transparent reduced graphite. The graphite oxide layer can be tuned to have varying degrees of oxidation through the layer such that three different wavelengths of light, 221, 222, and 223, can be absorbed and transformed into electrostatic potential energy, and a reduced graphene oxide film where negative charges of the electron hole pair can be collected. The degree of oxidation of each section of the graphite oxide will be tuned to the penetration depth of the wavelength it is intended to absorb. Optionally, the most oxidized layer can be closest to top of the cell where sunlight exposure occurs. The exposed surface of the top, highly oxidized layer can be completely reduced by exposure to visible laser light to make a very thin, transparent reduced graphene oxide electrode 213 where electron-hole recombination will occur. The bottom layer 211 can be photoreduced using UV light exposure, creating a buckled reduced graphite oxide that will act as the electron acceptor. This layer can be further functionalized with nitrogen to improve open circuit voltage. The film can be mounted on an aluminum contact, such as 202, and copper electroplating can be used to deposit contacts 203 to the top of the device in the rectangular pattern.

The structure in FIGS. 1 and 2 illustrate a photovoltaic device where the current collectors are disposed on a top and a botton surface. However, other configurations can be created using different construction techniques. For example, microfabrication techniques could be used to incorporate electrodes into each portion of the integrated layer, where one electrode could be created in contact with the graphite oxide, the reduced graphite oxide created, and an electrode then created in contact with the reduced graphite portion. Alternatively, vertically aligned photovoltaic device could be created using a structure such is as shown in FIG. 6. The photovoltaic device can be created using a series of cells 600. The cell can have a transparent electrode 601 and a second electrode 602, and spanning the two electrodes can be integrated layers 610 of reduced graphite oxide and graphite oxide

Another embodiment of the disclosure can be a method for fabricating a photovoltaic device. The method can include depositing at least one layer of graphite oxide over a first electrode, reducing a portion of the layer of graphite oxide to reduced graphite oxide, and depositing a second electrode on the reduced graphite oxide. The step of reducing a portion of the layer of graphite oxide to reduced graphite oxide creates an integrated layer of reduced graphite oxide and graphite oxide. As disclosed above, the integrated layer of reduced graphite oxide and graphite oxide forms an intrinsic p/n junction in the photovoltaic material.

In an embodiment, the first electrode can be a reduced graphite oxide layer. Alternatively, a reduced graphite oxide layer can be applied to the first electrode, and the graphite oxide can be layered upon it.

The method can also include subsequent additions of integrated layer by repeating the steps of depositing the graphite oxide and then reducing the graphite oxide. Thus the method can further comprise depositing at least one layer of graphite oxide over the previous integrated layer, and reducing a portion of the graphite oxide to a reduced graphite oxide to create a new integrated layer.

The step of depositing the graphite oxide can be conducted in one operation or in an series of operations. For example, the deposition of the graphite oxide can be as one layer of graphite oxide as a single pad. Alternatively, the graphite oxide can be deposited in a series of layers. The layers can be cast by any method for casting multiple layers of a solid. The layers can be added by spincoating the graphite oxide onto the surface. The layers can be added by dropcasting the graphite oxide onto the surface. The layers of graphite oxide added in the deposition step can be the same oxygen content and same material, in which case the overall layer of graphite oxide prior to reduction has a uniform oxygen content. Alternatively, the layers of graphite oxide added in the deposition step can have a variable oxygen content, in which case the overall layer of graphite oxide prior to reduction can have a variable amount of oxygen content. That variation between each section can be random, alternating, increasing or decreasing. The variation can be used to create a gradient of oxygen content in the graphite oxide layer, prior to reduction.

The oxygen content of the graphite oxide deposited in the method can be as disclosed above, and can graphite oxides with oxygen content of greater than 10%, and can have a oxygen content of less than about 45%. The graphite oxide can have an oxygen content between about 10% and about 40%, between about 15% and about 40%, and between about 15% and about 35%. The graphite oxide content can have an oxygen content between about 15% and about 25%, between about 20% and about 30%, or between 25% and about 35%. The percentage here is atom%, based on XPS measurements.

By layering graphite oxide in portions of layer of graphite oxide, the different portions can be varied in ways other than oxygen content. For example, some layers of the graphite oxide can further include a dopant for that portion of the eventual integrated layer. In one example, a p-type dopant could be included in one section of the graphite oxide that does not get reduced. Alternatively, an n-type dopant could be included in a portion of the graphite oxide that does get reduced. More particularly, a p-type dopant could be included in the first graphite oxide layer deposited in the a spincoating or drop coating process, then subsequent layers of graphite oxide on top of the p-doped layer could be added that do not have any dopant. Reduction of the upper layers can then produce the reduced graphite oxide layer which is integrated with a graphite oxide that would contain a p-type dopant.

In the method, once the at least one layer of graphite oxide is deposited, a portion of that layer can be reduced to a reduced graphite oxide, which thereby creates the integrated layer of graphite oxide and reduced graphite oxide. The reduction can be conducted by a photolytic process, i.e. a photolytic reduction. The photolytic reduction can be conducted using any light source capable of reducing the graphite oxide. In an embodiment, the light source can be a high intensity light source. The light source can be a laser process, such as a laser excimer process. One such process is demonstrated in U.S. Pat. No. 8,883,042, and in Carbon, 53, (2013), pp. 81-89, each of which are incorporated by reference. However, other light sources can also be used, such as flash lamps, discharge lamps, and so forth.

In the method, the photolytic reduction can be conducted in an inert atmosphere or under vacuum. The inert atmosphere can include gases such as the inert/noble gases or nitrogen. Under some conditions using laser processing, the nitrogen can also act as an n-doping source, via a plasma interaction using a focused laser. Thus, the method can further include reducing the graphite oxide to reduced graphite oxide while also n-doping the integrated layer with nitrogen atoms.

In an embodiment of the method, the reduced graphite oxide can have an oxygen content as described above, and can have an oxygen content of greater than about 1% and can have a oxygen content of less than about 20%. The oxygen content of the reduced graphite oxide can be between about 2% and about 20%, between about 2% and about 15%, and between about 4% and about 14%. The oxygen content of the reduced graphite oxide can be between about 2% to about 8%, between about 4% and about 10%, or about 8% to about 15%. The percentage here is atom %, based on XPS measurements.

The method for preparing these devices and the technology in the devices themselves can be exemplified in the following nonlimiting example.

Graphite oxide (GO) solutions were prepared using the modified Hummers method by oxidizing graphite powder (325 mesh) for 7 days followed by purification through dilution with nanopure water and centrifugation cycles rather than filtration. The purification procedure was repeated until the solution reached pH 7. Freestanding graphite oxide films were produced by filtering the concentrated graphite oxide solution with high pressure (170 psi head pressure) filtration funnel (Pall Corporation) through the 47 mm diameter Whatman nylon filter membrane with 200 nm pores. The filtered graphite oxide on the nylon membrane was dried for 24 hrs at 150° C. in an oven to produce freestanding graphite oxide films with 18.1% oxygen content (4.47 CIO ratio). To produce graphite oxide with a 34.1% oxygen content (1.90 C/O ratio), the freshly filtered graphite oxide film was dried in a desiccator (Drierite drying agent) at room temperature for 72 hrs. For convenience, these samples will be named GO18 and GO34, respectively. The oxygen content was determined with X-ray photoelectron spectroscopic (XPS) analysis.

Laser reduction was performed with a Lambda Physic LPX-300 KrF excimer laser with an excitation wavelength of 248 nm. Excimer laser reduced graphite oxide films were produced by irradiating GO18 with 32 laser pulses under ultrahigh purity N₂ purging and GO34 with 64 laser pulses under ˜1×10⁻² ton vacuum. The laser fluence was set to −140 mJ/cm² and the repetition rate to 1 Hz.

FIGS. 3A-E present the rGO and GO characterizations. FIG. 3A shows Raman spectra of the GO and rGO recorded with a micro-Raman system using 532 nm excitation line. A power of 2 mW was used with 1 μm spot-size to avoid further photoprocessing of the sample. The spectra were normalized with respect to G peak. FIG. 3B shows Scanning Electron Microscope (SEM) image of the GO and FIG. 3 C includes the SEM image of rGO surfaces showing the morphology of the reduced graphene sample. FIG. 3D presents topography AFM image of rGO and FIG. 3E presents the conductive AFM image of rGO, which represents conductivity of the rGO surface shown in FIG. 3D. Note that both topography and conductivity images of rGO surfaces were taken simultaneously.

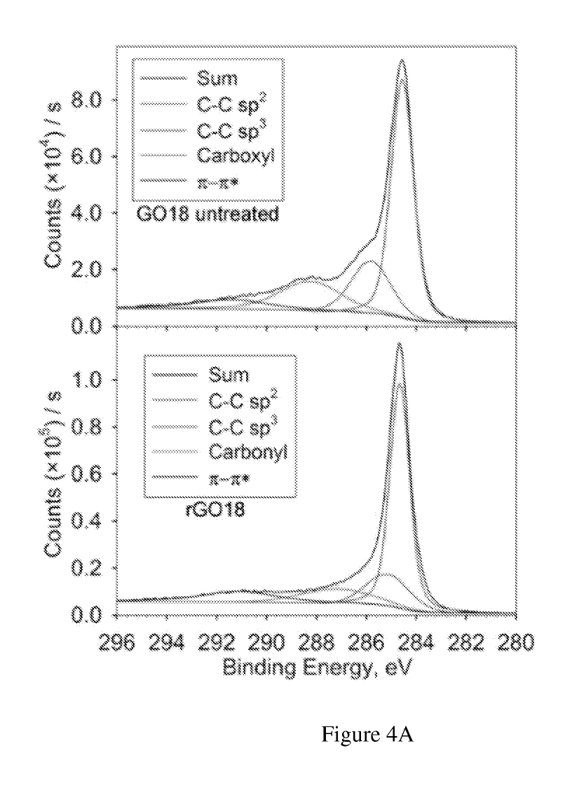

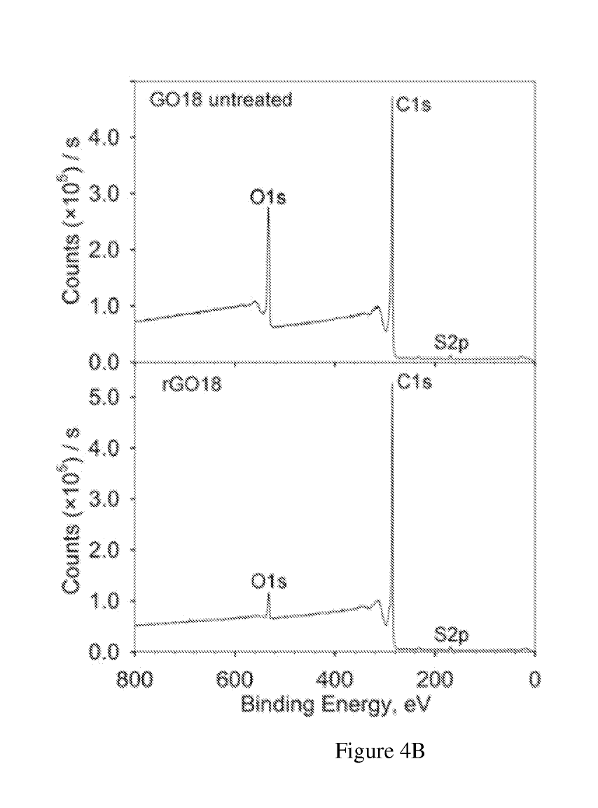

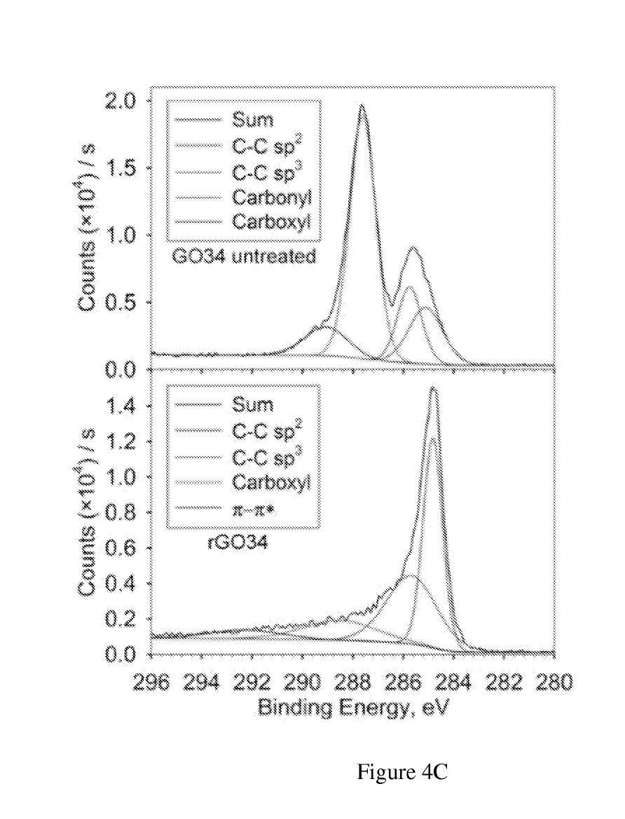

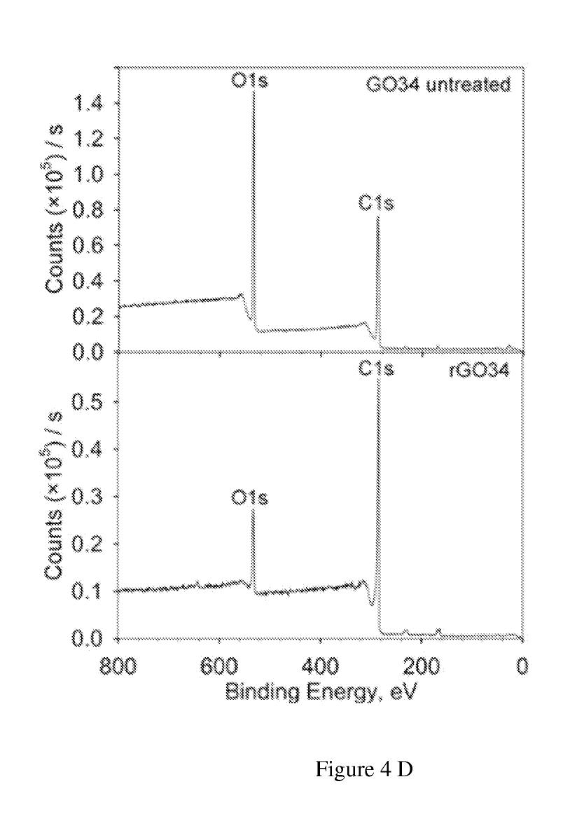

FIGS. 4 A-D present X-ray photoelectron spectroscopy of rGO and GO. FIG. 4A shows a typical high resolution spectra of the C1s peak of the untreated GO18 and the excimer laser reduced graphite oxide rGO18. The O1s peak shows a dramatic reduction from the GO18 untreated sample spectra to rGO18 spectra. FIG. 4B presents XPS analysis of the untreated graphite oxide GO18 and the excimer laser reduced graphite oxide rGO18. The spectra were recorded with the Thermo Scientific K-Alpha XPS system. (Al Ka X-ray source, 400 μm spot size). rGO18 spectra shows a significant reduction of the highlighted peaks and the reduction of the carboxyl and C—C spa peaks in respect to the C—C sp2 and π-π* peaks. FIG. 4C presents a high resolution spectra of the C1s peak of the untreated GO34 and reduced GO34 samples. FIG. 4D presents XPS analysis of the untreated GO34 and rGO34 samples, indicating the absence of the π-π* band for GO34 untreated sample and presence of the high intensity peaks presenting a carboxyl group. These peaks significantly reduced the intensities under the laser reduction process and C—C sp² band shows a higher intensity peak for rGO34.

The reduction to rGO was verified with the Raman (FIG. 3A) and X-ray photoelectron (FIG. 4A-D) spectroscopies and the surface morphology was investigated with scanning electron microscopy (SEM) and conductive imaging atomic force microscopy (I-AFM) (See FIG. 3. B, C and D, E respectively). The Raman spectra of GO18 shows the presence of sp³ defects ˜1351 cm⁻¹ and the in-plane vibration of sp² bonded carbon atoms ˜1590 cm⁻¹. The weak and broad shape of the G′ centered around 2665 cm⁻¹ is sensitive to the chemical doping such as presence of oxygen and also indicates the existence of disorder. The Raman spectrum of the laser reduced GO18 shows that D-band (˜1348 cm⁻¹) intensity is significantly reduced with respect to G band (˜1580 cm⁻¹), suggesting that laser irradiation reduces the presence of high density of defects and structural disorders in rGO. The blue shift of the G′ band (˜2684 cm⁻¹) suggests that the amount of oxygen was reduced due to laser irradiation in N₂ and this result was confirmed with XPS analysis (FIG. 2). The increase of the G′ for rGO also suggests that the disorder was dramatically reduced and that the average site of the sp² domains increases from 18.2 nm to 56.5 nm.

The atomic force microscopy (AFM) and conductive atomic force microscopy (I-AFM) data presented in FIG. id and FIG. 1e were taken simultaneously. These images represent the typical topography of the rGO surface and resistance maps across the reduced area of the GO. The taller features on the AFM topological image corresponds to areas of with high resistance in the I-AFM images. The lowest resistance zones correspond to highly reduced graphene oxide “valleys” (i.e. areas mainly within the troughs—FIG. 3E).

XPS analysis (FIGS. 4A-D) was used to further confirm graphite oxide reduction. FIGS. 4A-D shows the spectrum for the untreated GO18 and GO34 samples. A significant amount of oxygen is observed in both GO18 (˜18.1%) and GO34 (34.1%) materials. The carbon to oxygen (C/O) ratio is 4.47 for GO18 and 1.90 for GO34, respectively. The spectrum of the excimer laser rGO18 (FIG. 4B) confirms that the amount of oxygen is decreased to ˜4.71%, and the C/O ratio is increased to 20.04. FIG. 2d confirms the decrease in oxygen content for GO34 to 14.5% and the C/O ratio increase to 5.5. The high resolution analysis of the C1s peak for the GO18 before the reduction (FIG. 4B) reveals the presence of peaks associated with sp² and sp³ hybridized carbon as well as the oxygen containing functionalities in the form of carboxyl groups. The laser reduced GO18 has a dominant sp² peak as well as minor peaks associated with sp³ hybridized carbon and carbonyl groups. The C1s peak analysis of the untreated GO34 sample (FIG. 4D) demonstrates the presence of peaks corresponding to sp² and sp³ hybridized carbon as well as the carbonyl and carboxyl groups. The laser reduced GO34 mostly has the peaks attributed to sp² and sp³ hybridized carbon and carboxyl groups.

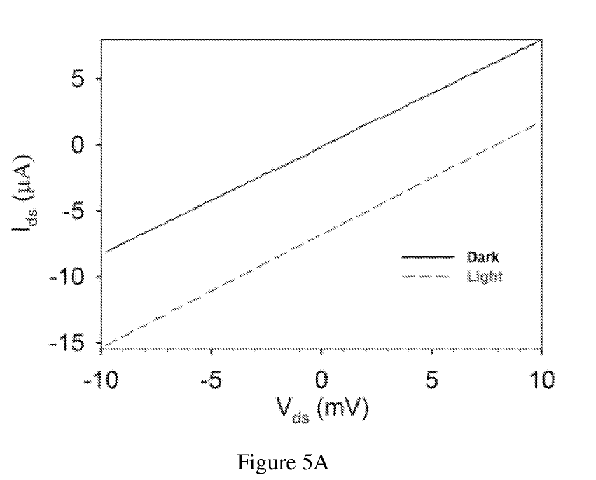

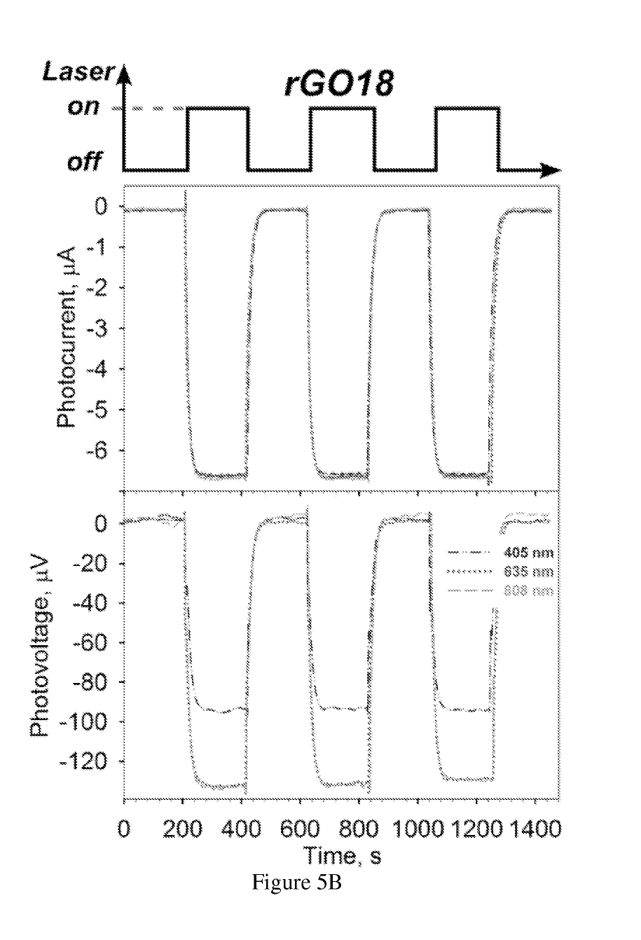

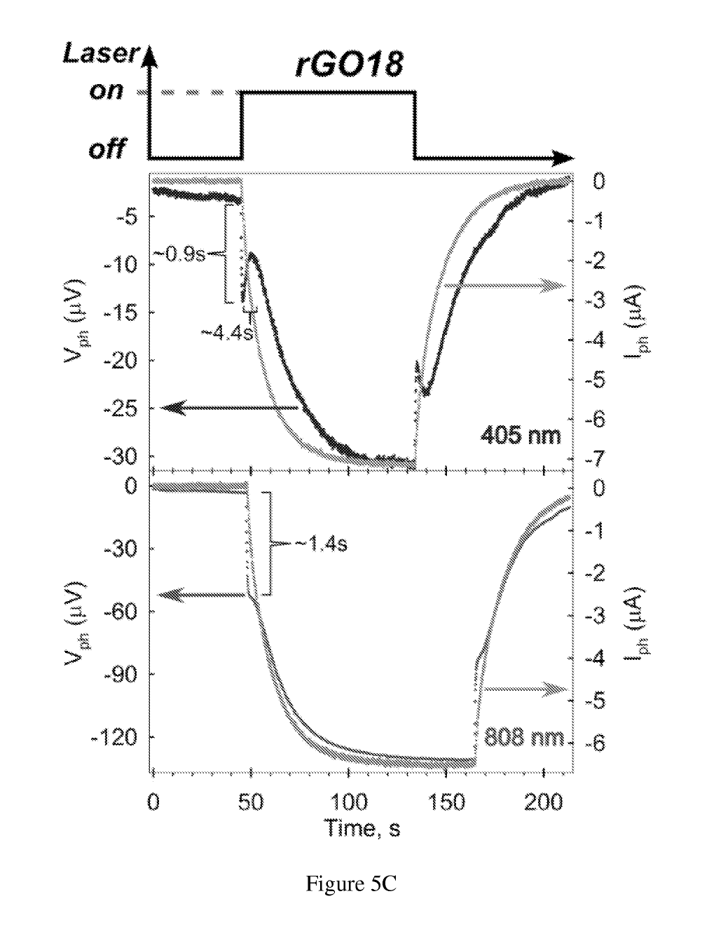

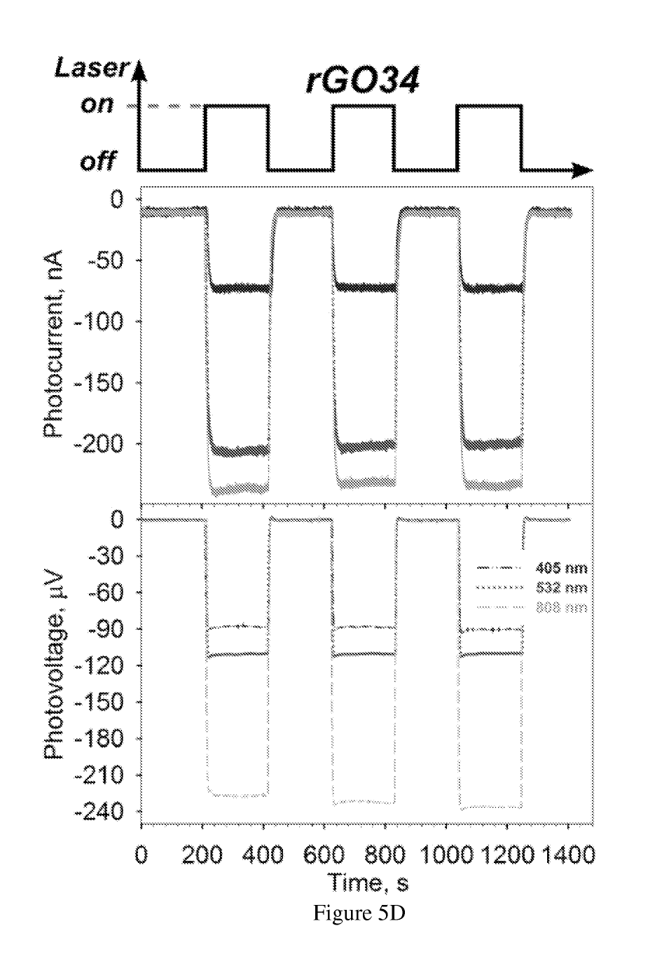

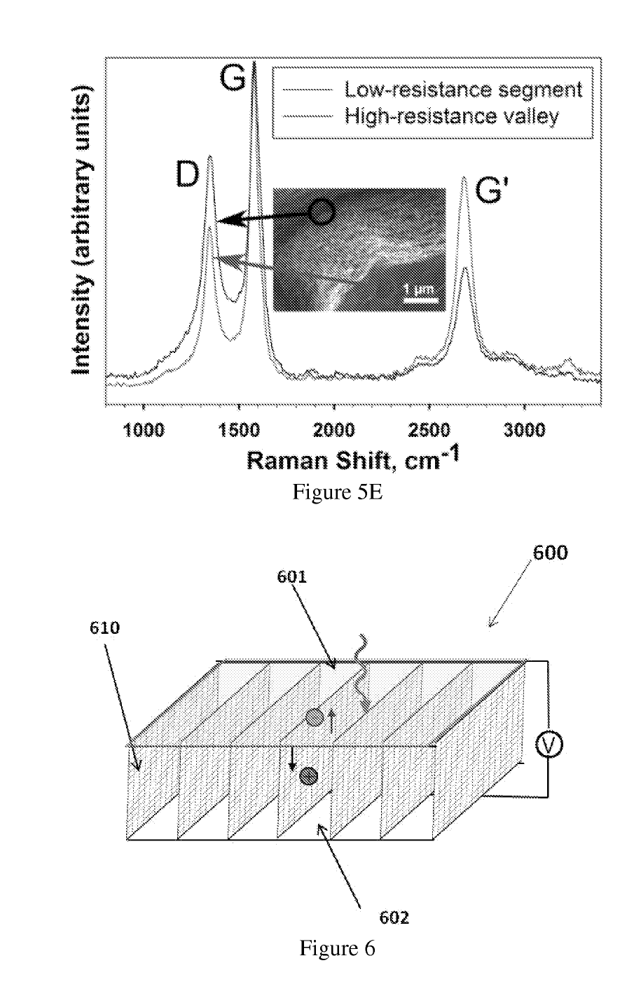

FIG. 5A-E characterize the rGO photo detector. FIG. 5A show typical I-V curves of the rGO photo detector without and with light illumination. FIG. 5B demonstrates time resolved photocurrent and photo voltage generation with illumination toggling between “on” and “off” for the rGO18 photo detector. FIG. 5C shows photoresponse dynamics of the rGO18 photo detector. When the 405 nm illumination was switched on, the faster photoresponse of p-type GO generates the Vₚₕ. On the 0.9th sec the Vₚₕ was offset by relative slow photoresponsive microdefects acting as micro-capacitors. Similar features are found right after when illuminations were turned off. These features are invisible for 643 and 808 nm wavelength illuminations. FIG. 5D shows time resolved photocurrent and photo voltage of the rGO34 photo detector. FIG. 5E shows Raman spectra of rGO high-resistance valley and low-resistance segments. The arrows in the inset indicate positions where Raman spectra were recorded. The spot sizes are not scaled with respect to the SEM image scale.

Photocurrent generation experiments were performed with 405 nm, 635 nm and 808 nm light source wavelengths. FIG. 5A shows current measurements as a function of source-drain voltage with and without illumination. There is no gate voltage and the dark current extrapolates through the origin as expected. The magnitude of the photocurrent strongly depends on the location of the illumination. The strongest photocurrent is observed near metal-graphene contacts due to the strongest electric (E)-fields. Usually, the internal electric fields due to the metal-graphene contact only exist in narrow regions ˜(0.2 μm) near electrode-graphene interfaces. This internal field is responsible for the charge transfer between metal and graphene and creates a band bending effect which leads to p-n-junction formation. The electrodes used in our experiments consist of the same metal. Because of the metal symmetry between the electrodes, the contribution of the internal E-fields from each electrode should nullify the total photocurrent. Thus, the photocurrent cannot be attributed to asymmetry effects resulting from different electrode materials. For clear separation of the photocurrent generation from the electrode-induced fields, we examined rGO channels of at least ˜3 mm long.

The dynamic photoresponse curves are shown in FIG. 5B were measured using a Van der Pauw 4-point probe configuration. The devices were based on the rGO18 thin film on top of GO with a total combined thickness of 6 μm. The graphene thickness is difficult to measure but is expected to be significantly thinner than the underlying graphite oxide. Each dynamic response curve is shown for three cycles of the photoexcitation source being turned on and off to demonstrate the reproducibility of the data with a time interval of 3.5 min. The power of each excitation source was kept at 20 mW over a 1 mm diameter spot size. Note that to determine the current fluxes in these systems, the current should be divided by the area of the irradiated spot, to give mA/cm².

We calibrated the device photoresponse based on the photocurrent signal for each light source wavelength in order to see the photo voltage (Vₚₕ) difference generated with no source-drain voltage (V_{sd}) applied across the device. In order to get the same photocurrent response for the different wavelengths, the collimated excitation source was passed through series of power reducing filters and then was focused on the device surface

As FIG. 5B shows, the lowest Vₚₕ is registered for 405 nm wavelength illumination. The highest Vₚₕ is recorded for 808 and 643 nm light sources respectively. The photoresponsivity defined by the ratio of photocurrent to dark current I_{sd}(light)/I_{sd} (dark)˜223 which is a significant increase compared to results in recent reports. An observation of the photocurrent on the rGO samples is related to the unique morphology of the reduced graphene oxide surfaces after the excimer laser reduction procedure. SEM images (FIG. 3B,C) and conductivity and topography AFM images (FIG. 3D,E) show that the rGO surface consists of extensive low-resistance and photosensitive segments ˜10-20 μm² separated by high-resistance, less photoconductive valleys between them with widths of −0.2 μm. The high-resistance valleys are represented as the dark areas, and low-resistance regions are bright on the conductivity AFM image (FIG. 3 E). Photogenerated electron-hole pairs in the GO/rGO interface normally would recombine on a time scale of tens of picoseconds, depending on the quality of the rGO film.^{[17,18]} The asymmetric shape of the segments and valleys forms uneven internal E-fields which may be partially responsible for the separation of the photo-generated carriers. Under such conditions, the current passing through the sample at low fields is controlled by high resistance segments. As the photo-generated voltage rises, the injection of the space charge begins to determine the current in the high-resistance segments. At the appropriate level of injection, the resistance of these segments becomes commensurate with that of the low-resistance segments and the asymmetrical nature of the internal E-fields throughout the device surface generates photocurrent across the whole sample.

The intensity of D-bands in FIG. 5E indicates smaller presence of the defects in low-resistance segments compared to the high-resistance valleys. Defects are playing the role of the trapping levels or recombination centers in rGO. In addition to defects, dislocations and regions of uneven doping affect the photoelectric properties of the device especially under the 405 nm wavelength illumination. Since rGO has a slightly better absorbance at 405 nm^{[20]} and the penetration depth is lower compared to 643 and 808 nm wavelength illuminations. Therefore, there are more trapping levels which can offset Vₚₕ When these levels saturated in ˜4.4 sec (FIG. 5C), the Vₚₕ generates at the slower rate for all illuminations. The change, in rate of generation Vₚₕ, indicates that the defects which are deeper located in rGO saturated in a longer time until the system riches equilibrium. Similar process of the deep and shallow photoelectron trapping was observed in ITO/TiO₂ systems. The morphology of the samples produced by the laser reduction method plays an important role in photo voltage generation, and the oxygen content of the sample can have an important role as well. FIG. 5D shows the levels of photo voltage generated under 405,532 and 808 nm wavelength illuminations. The photocurrent levels in these rGO34 were not as high as in rGO18 samples, but the photovoltages have shown 1.6 times higher photo voltage under 808 nm illumination and exactly the same Vₚₕ under 405 nm illumination.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

1-31. (canceled)

32. A reduced graphite oxide photovoltaic device, comprising
one or more integrated layers of reduced graphite oxide and graphite oxide, and
current collectors located on different sections of the one or more integrated layers,
wherein the reduced graphite oxide is intimately associated with and overlays the graphite oxide in the integrated layer.

33. The photovoltaic device of claim 32, wherein the reduced graphite oxide and graphite oxide form an intrinsic p/n junction.

34. The photovoltaic device of claim 32, wherein the reduced graphite oxide is intimately associated with graphite oxide in the integrated layer, and does not encapsulate the graphite oxide in the integrated layer.

35. The photovoltaic device of claim 32, wherein the reduced graphite oxide further includes an n-dopant, and/or the graphite oxide further includes a p-dopant.

36. The photovoltaic device of claim 32, wherein the oxygen content of the reduced graphite oxide in at least one integrated layer is between 1% and 20%.

37. The photovoltaic device of claim 32, wherein the oxygen content of the reduced graphite oxide in at least one integrated layer is between 4% and 14%.

38. The photovoltaic device of claim 32, wherein the oxygen content of the graphite oxide in at least one integrated layer is between 15% and 40%.

39. The photovoltaic device of claim 32, wherein the oxygen content of the graphite oxide in at least one integrated layer is between 15% and 30%.

40. The photovoltaic device of claim 32, comprising two or more integrated layers of reduced graphite oxide and graphite oxide.

41. The photovoltaic device of claim 32, wherein the integrate layer includes a reduced graphite layer and at least two different layers of graphite oxide, the graphite oxide layers having at least two different oxygen content values.

42. The photovoltaic device of claim 32, wherein the at least one integrated layer of reduced graphite oxide and graphite oxide absorbs a broad band of light between 300 nm and 3000 nm.

43. The photovoltaic device of claim 42, wherein the broad band of visible light comprises wavelengths from 400 nm to 850 nm.

44. A method of fabricating a photovoltaic device, the method comprising:
depositing at least one layer of graphite oxide over a first electrode;
reducing a portion of the layer of graphite oxide to reduced graphite oxide to created an integrated layer of reduced graphite oxide and graphite oxide;
depositing a second electrode over reduced graphite oxide

45. The method of claim 44, further comprising adding additional integrated layers of reduced graphite oxide and graphite oxide by
depositing at least one layer of graphite oxide over the previous integrated layer; and
reducing a portion of the graphite oxide to reduced graphite oxide to create a new integrated layer.

46. The method of claim 44, wherein the graphite oxide is converted to reduced graphite oxide by photolytic reduction of a portion of the graphite oxide.

47. The method of claim 46, wherein the photolytic reduction is conducted in an inert gas atmosphere or under vacuum.

48. The method of claim 46, wherein the photolytic reduction is conducted by a high intensity light source such as laser processing, arc lights, or flash lamps.

49. The method of of claim 44, wherein the graphite oxide layer can be deposited as multiple layers of graphite oxide.

50. The method of claim 44, wherein the oxygen content of the graphite oxide in at least one integrated layer is between 15% and 40%, and the oxygen content of the reduced graphite oxide in at least one integrated layer is between 1% and 20%.

51. The method of claim 44, wherein reducing the graphite oxide to reduced graphite oxide also includes n-doping the integrated layer.

52. The method of claim 44, wherein the graphite oxide layer can be deposited with an n-dopant and/or a p-dopant.
